(19) United States
(12) Patent Application Publication
(10) Pub. No.: US 2026/0018497 A1
(43) Pub. Date: Jan. 15, 2026

(54) MULTI-PHASE SILICON CARBIDE PACKAGING STRUCTURE

(71) Applicant: HiPer Semiconductor Inc., George Town (KY)

(72) Inventor: CHENG-CHIEH HSU, Zhubei City (TW)

(21) Appl. No.: 19/220,872

(22) Filed: May 28, 2025

(30) Foreign Application Priority Data
Jul. 11, 2024 (TW) 113126061

(51) Int. Cl. H01L 23/495; H01L 23/00; H01L 23/31; H01L 23/373

(52) U.S. Cl. CPC H01L 23/49568; H01L 23/3107; H01L 23/3735; H01L 23/49562; H01L 24/40; H01L 2224/40137; H01L 2224/40245; H01L 2924/10272; H01L 2924/1306

(57) ABSTRACT

A packaging structure includes heat dissipation substrate, a lead frame, multiple half-bridge modules, and a package body. The heat dissipation substrate has a metal routing. The lead frame is coupled to the heat dissipation substrate and includes a power pin and a ground pin. Half-bridge modules connect in parallel between the power pin and the ground pin. Each half-bridge module includes a high-side SiC transistor, a low-side SiC transistor and a first clip. The high-side SiC transistor and the low-side and the SiC transistor are flip-chip mounted on the corresponding position of the metal routing of the heat dissipation substrate. The source electrode of the high-side SiC transistor is coupled to the drain electrode of the low-side SiC transistor through the first connecting piece and the metal routing. The package covers the heat dissipation substrate, multiple sets of half-bridge modules and part of the lead frame.

### BACKGROUND

### 1. Technical Field

The present disclosure relates to a multi-phase silicon carbide (SiC) module packaging structure, and more particularly to a packaging structure in which at least two half-bridge modules are packaged within the same package body. This packaging structure not only reduces assembly cost but also improves heat dissipation of the multi-phase SiC module and reduces power loss.

### 2. Description of the Related Art

Silicon carbide power devices possess characteristics such as high temperature resistance, high voltage tolerance, and low on-resistance. In addition, compared to conventional silicon power devices, silicon carbide power devices can significantly reduce switching losses and enable a smaller overall module footprint. As such, silicon carbide power devices are currently widely used in photovoltaic power conversion circuits and electric vehicles. However, the current process of assembling multiple discrete half-bridge switches into a single power module is complex and time-consuming, which increases assembly costs. Moreover, assembling multiple discrete half-bridge switches is prone to assembly errors, thereby necessitating improvements.

### SUMMARY

An object of the present disclosure is to provide a multi-phase silicon carbide (SiC) module packaging structure, in which at least two half-bridge modules are packaged within the same package body. This packaging structure not only reduces assembly cost but also improves the heat dissipation of the multi-phase silicon carbide module and reduces power loss.

To achieve the above objective, a multi-phase silicon carbide (SiC) packaging structure of the present disclosure includes a heat dissipation substrate, a lead frame, a plurality of half-bridge modules, and a package body. The heat dissipation substrate is provided with a metal routing. The lead frame is coupled to the heat dissipation substrate and includes a power pin and a ground pin. The half-bridge modules are connected in parallel between the power pin and the ground pin. Each half-bridge module includes a high-side silicon carbide (SiC) transistor, a low-side silicon carbide (SiC) transistor, and a first clip, wherein the high-side SiC transistor and the low-side SiC transistor are flip-chip mounted on corresponding locations of the metal routing of the heat dissipation substrate. The source of the high-side SiC transistor is coupled to the drain of the low-side SiC transistor through the first clip and the metal routing. The package body encapsulates the heat dissipation substrate, the half-bridge modules, and a portion of the lead frame.

According to one embodiment of the present disclosure, the packaging structure further includes at least one second clip, wherein the power pin is coupled to the drain of each of the high-side SiC transistor through the at least one second clip and the metal routing.

According to one embodiment of the present disclosure, the packaging structure further includes at least one third clip, wherein the ground pin is coupled to the source of each of the low-side SiC transistor through the at least one third clip and the metal routing.

According to one embodiment of the present disclosure, the packaging structure further includes a heat dissipation plate, the heat dissipation plate has a first surface and a second surface opposite to the first surface, the package body includes a package top surface, wherein the first surface is coupled to the drain of each of the low-side SiC transistors through the at least one first clip, and the second surface is exposed from the package top surface.

According to one embodiment of the present disclosure, the package body includes a package bottom surface, the heat dissipation substrate is a Direct Bond Copper (DBC) substrate, a Direct Bond Aluminum (DBA) substrate, or an Active Metal Brazing (AMB) substrate, and the heat dissipation substrate includes a heat dissipation surface, the heat dissipation surface is exposed from the package bottom surface.

According to one embodiment of the present disclosure, the power pin and the ground pin of the packaging structure are respectively located on opposite sides of the package body.

According to one embodiment of the present disclosure, the packaging structure further includes a plurality of high-side gate pins and a plurality of low-side gate pins, and the high-side gate pins and the low-side gate pins are located on the same side of the package body.

According to one embodiment of the present disclosure, the number of the half-bridge modules is three, the number of the second clip is three, and the number of the third clip is three, when the multi-phase SiC module is a three-phase bridge inverter, the lead frame includes a U-phase pin, a V-phase pin, and a W-phase pin.

According to one embodiment of the present disclosure, the U-phase pin, the V-phase pin, the W-phase pin, and the ground pin of the packaging structure are located on the same side of the package body.

Through the multi-phase SiC packaging structure of the present disclosure, at least two half-bridge modules, or three half-bridge modules, can be packaged within the same package body. This configuration not only improves the conversion efficiency of the multi-phase SiC module and reduces the assembly cost of the half-bridge module, but also achieves double-sided heat dissipation by exposing both the heat dissipation surface of the heat dissipation substrate and the second surface of the heat dissipation plate from the package body, thereby improving heat dissipation and reducing power loss of the multi-phase SiC module.

### BRIEF DESCRIPTION OF THE DRAWINGS

FIG. 1 is a plan schematic view of one embodiment of the packaging structure of a multi-phase SiC module according to the present disclosure.

FIG. 2 is a cross-sectional schematic view of one embodiment of the packaging structure of a multi-phase SiC module according to the present disclosure.

FIG. 3 is a circuit diagram of one embodiment of the packaging structure of a multi-phase SiC module according to the present disclosure.

FIG. 4 is a top view of one embodiment of the packaging structure of a multi-phase SiC module according to the present disclosure.

FIG. 5 is a bottom view of one embodiment of the packaging structure of a multi-phase SiC module according to the present disclosure.

### DETAILED DESCRIPTION OF THE EMBODIMENTS

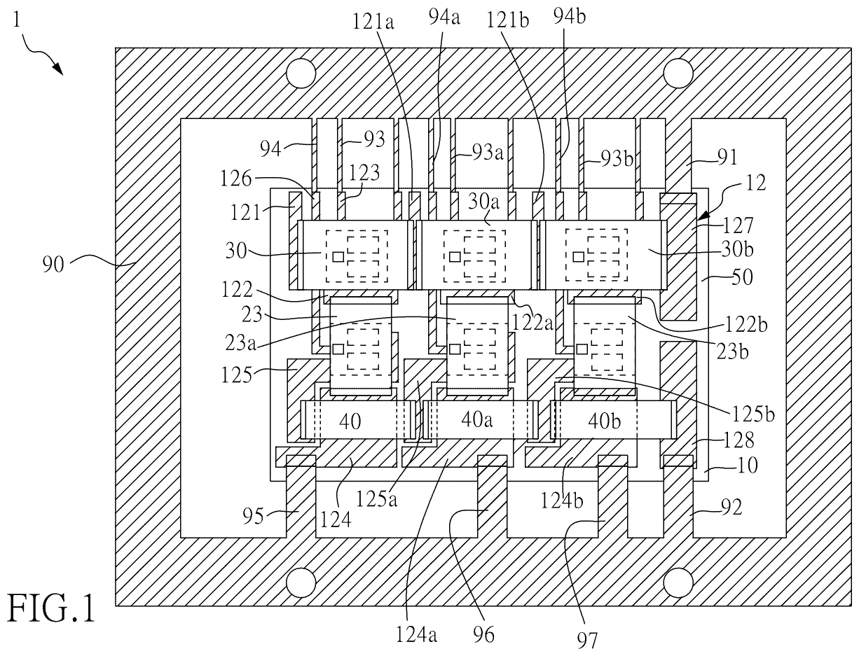

To better understand the technical content of the present disclosure, a preferred embodiment is described below. Please refer to FIG. 1 to FIG. 5, which respectively illustrate a plan schematic view, a cross-sectional view, a circuit diagram, a top view, and a bottom view of an embodiment of the multi-phase silicon carbide (SiC) packaging structure of the present disclosure.

As shown in FIG. 1 to FIG. 3, according to one embodiment of the present disclosure, the multi-phase SiC packaging structure 1 includes a heat dissipation substrate 10, a lead frame 90, three half-bridge modules 20, 20a, and 20b, three second clips 30, 30a, and 30b, three third clips 40, 40a, and 40b, and a package body 50. The package body 50 encapsulates the heat dissipation substrate 10, the half-bridge modules 20, 20a, and 20b, the second clips 30, 30a, and 30b, a portion of the lead frame 90, and the third clips 40, 40a, and 40b. The heat dissipation substrate 10 is provided with a metal routing 12. The lead frame 90 is coupled to the heat dissipation substrate 10 and includes a power pin 91 and a ground pin 92. The power pin 91 and the ground pin 92 are located on opposite sides of the package body 50, and the three half-bridge modules 20, 20a, and 20b are connected in parallel between the power pin 91 and the ground pin 92. According to one embodiment of the present disclosure, the multi-phase SiC module using the packaging structure 1 of the present disclosure can be employed in power conversion devices such as a power inverter for converting direct current to alternating current, a photovoltaic (PV) inverter, a three-phase bridge inverter, or a variable frequency drive (VFD), although the invention is not limited to the foregoing examples.

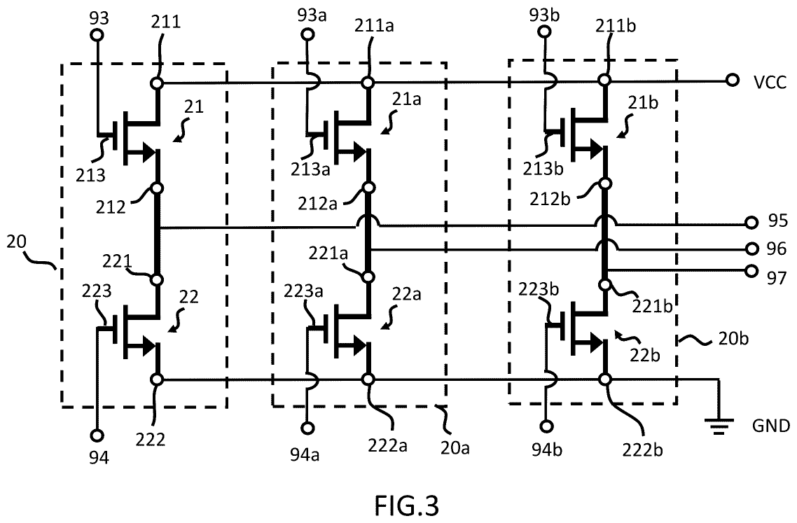

As shown in FIG. 1 to FIG. 3, in this embodiment, the half-bridge modules 20, 20a, and 20b respectively include a high-side transistor 21, 21a, 21b, a low-side transistor 22, 22a, 22b, and a first clip 23, 23a, 23b. The high-side transistor 21, 21a, 21b and the low-side transistor 22a, 22b are mounted in a flip-chip configuration and are coupled to the heat dissipation substrate 10 through solder 100. In this embodiment, the solder 100 can be sintered silver or solder paste. Both the high-side transistor 21, 21a, 21b and the low-side transistor 22, 22a, 22b are silicon carbide transistors (SiC FETs). However, the present disclosure is not limited thereto; other types such as semiconductor field-effect transistors (FETs) or aluminum gallium nitride (AlGaN)/gallium nitride (GaN) high electron mobility transistors (HEMTs) are also applicable to the present disclosure. It is noted that FIG. 3 illustrates the high-side transistor 21, 21a, 21b and the low-side transistor 22, 22a, 22 as n-type silicon carbide metal-oxide-semiconductor field-effect transistors (SiC MOSFETs) by way of example. However, the present disclosure is not limited to the configuration shown in FIG. 3; p-type SiC MOSFETs and HEMTs are also suitable for use with the present disclosure.

As shown in FIG. 1 to FIG. 3, the high-side transistors 21, 21a, 21b respectively include a high-side drain 211, 211a, 211b and a high-side source 212, 212a, 212b, while the low-side transistors 22, 22a, 22b respectively include a low-side drain 221, 221a, 221b and a low-side source 222, 222a, 222b. The metal routing 12 includes high-side drain wiring 121, 121a, 121b, high-side source wiring 122, 122a, 122b, high-side gate wiring 123, low-side drain wiring 124, 124a, 124b, low-side source wiring 125, 125a, 125b, low-side gate wiring 126, power wiring 127, and ground wiring 128. As shown in FIG. 1 to FIG. 3, the high-side sources 212, 212a, and 212b are respectively coupled to the corresponding low-side drains 221, 221a, and 221b through the first clips 23, 23a, and 23b, the high-side source wiring 122, 122a, and 122b, and the corresponding low-side drain wiring 124, 124a, and 124b. Specifically, as shown in FIG. 1 and FIG. 3, the high-side source 212 of the half-bridge module 20 is coupled to the corresponding low-side drain wiring 124 and the low-side drain 221 through the first clip 23 and the high-side source wiring 122. The high-side source 212a of the half-bridge module 20a is coupled to the corresponding low-side drain wiring 124a and the low-side drain 221a through the first clip 23a and the high-side source wiring 122a. The high-side source 212b of the half-bridge module 20b is coupled to the corresponding low-side drain wiring 124b and the low-side drain 221b through the first clip 23b and the high-side source wiring 122b.

The three second clips 30, 30a, and 30b are copper clips used to connect the high-side drains 211, 211a, and 211b in parallel to the power pin 91. Specifically, as shown in FIG. 1 to FIG. 3, in this embodiment, the second clip 30 is coupled to the high-side drain 211 and the high-side drain 211a through sintered silver or solder paste, and the high-side drain 211 and the high-side drain 211a are coupled to their corresponding high-side drain wiring 121, 121a through sintered silver or solder paste. The second clip 30a is coupled to the high-side drain 211a and high-side drain 211b through sintered silver or solder paste, and the high-side drain 211a and the high-side drain 211b are coupled to their corresponding high-side drain wiring 121a, 121b through sintered silver or solder paste. The second clip 30b is coupled to high-side drain 211b and power wiring 127 through sintered silver or solder paste, and the high-side drain 211b and the power pin 91 are respectively coupled to the corresponding high-side drain wiring 121b and power wiring 127 through sintered silver or solder paste, thereby allowing the high-side drains 211, 211a, and 211b of the half-bridge modules 20, 20a, and 20b to be connected in parallel to the power pin 91. It is noted that, according to one embodiment of the present disclosure, the effect of connecting the high-side drains 211, 211a, and 211b of the half-bridge modules 20, 20a, and 20b in parallel to the power pin 91 can also be achieved using only one second clip 30. Therefore, the number of second clips 30 is not limited to the embodiment described above.

The three third clips 40, 40a, and 40b are also copper clips used to connect the low-side sources 222, 222a, and 222b in parallel to the ground pin 92. Specifically, as shown in FIG. 1 to FIG. 3, in this embodiment, the third clip 40 is coupled to the low-side source 222 and the low-side source 222a through sintered silver or solder paste, and the low-side source 222 and the low-side source 222a are respectively coupled to the corresponding low-side source wiring 125, 125a through sintered silver or solder paste. The third clip 40a is coupled to the low-side source 222a and the low-side source 222b through sintered silver or solder paste, and the low-side source 222a and the low-side source 222b are respectively coupled to the corresponding low-side source wiring 125a, 125 through sintered silver or solder paste. The third clip 40b is coupled to the low-side source 222b and the ground wiring 128 through sintered silver or solder paste, and the low-side source 222b and the ground wiring 128 are respectively coupled to the low-side source wiring 125b and the ground pin 92 through sintered silver or solder paste, thereby allowing the low-side sources 222, 222a, and 222b of the half-bridge modules 20, 20a, and 20b to be connected in parallel to the ground pin 92. It is noted that, according to one embodiment of the present disclosure, the effect of connecting the low-side sources 222, 222a, and 222b of the half-bridge modules 20, 20a, and 20b in parallel to the ground pin 92 can also be achieved using at least one third clip 40. Therefore, the number of third clips 40 is not limited to the embodiment described above.

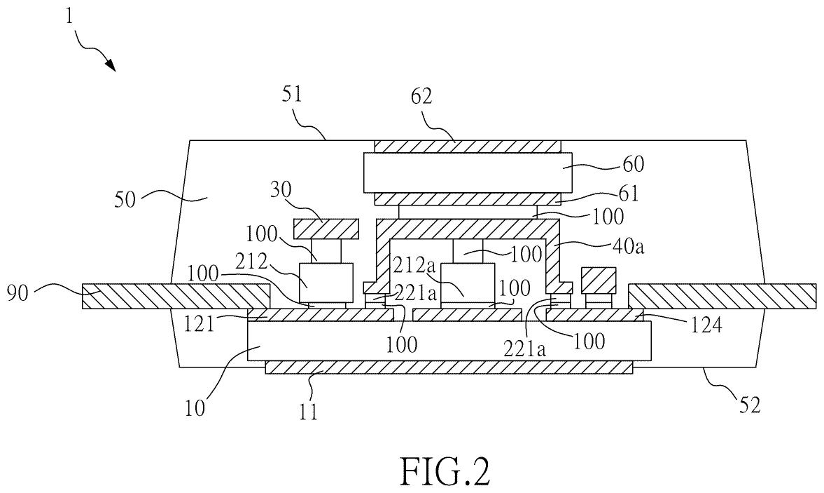

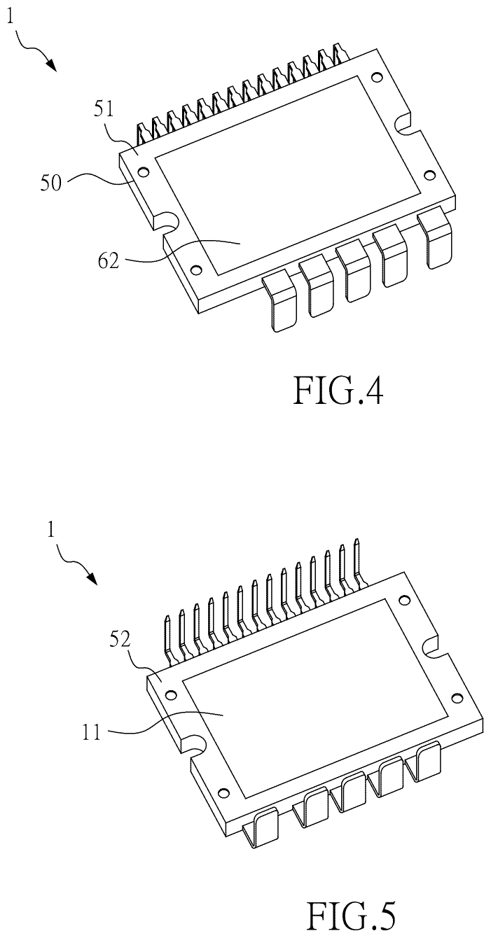

As shown in FIG. 2, FIG. 4, and FIG. 5, the package body 50 includes a package top surface 51 and a package bottom surface 52. The heat dissipation substrate 10 includes a heat dissipation surface 11, which is the surface of the heat dissipation substrate 10 where neither the high-side transistor 21 nor the low-side transistor 22 are mounted. The heat dissipation surface 11 is exposed from the package bottom surface 52. In this embodiment, the multi-phase SiC packaging structure 1 further includes a heat dissipation plate 60. The heat dissipation plate 60 includes a first surface 61 and a second surface 62 opposite to the first surface 61. The first surface 61 is coupled to the low-side drains 221, 221a, and 221b through the third clip 40, and the second surface 62 is exposed from the package top surface 51. According to one embodiment of the present disclosure, both the heat dissipation substrate 10 and the heat dissipation plate 60 are direct bond copper (DBC), direct bond aluminum (DBA), or active metal brazing (AMB) substrates. Therefore, the heat dissipation surface 11 and the second surface 62 are both copper-covered or aluminum-covered surfaces. This allows the package top surface 51 and the package bottom surface 52 of the package body 50 of the multi-phase SiC packaging structure 1 to have metal surfaces with excellent heat dissipation properties such as copper or aluminum, thereby improving the heat dissipation efficiency of the multiphase SiC module using the packaging structure 1 of the present disclosure and achieving reduced power loss.

In addition, although the embodiment shown in FIG. 1 to FIG. 3 illustrates an implementation with three sets of half-bridge module 20, 20a, 20b, in practice, two sets of half-bridge module 20, 20a are also applicable to the present disclosure. By removing one of the half-bridge module from the three sets of half-bridge modules 20, 20a, and 20b shown in FIG. 1 and FIG. 3, a configuration with two sets of half-bridge modules can be obtained. This modification is a straightforward adjustment that can be readily implemented by a person having ordinary skill in the art; therefore, detailed descriptions of the implementation with two sets of half-bridge modules 20 and 20a are omitted herein.

As shown in FIG. 1 to FIG. 3, according to one specific embodiment of the present disclosure, the lead frame 90 further includes three high-side gate pins 93, 93a, and 93b, and three low-side gate pins 94, 94a, and 94b, which are respectively coupled to the to the gates 213, 213a, and 213b of the high-side transistors 21, 21a, and 21b, and to the gates 223, 223a, and 223b of the low-side transistors 22, 22a, and 22b. Furthermore, when the multi-phase SiC module using the packaging structure 1 of the present disclosure is applied as a three-phase bridge inverter, the lead frame 90 includes a U-phase pin 95, a V-phase pin 96, and a W-phase pin 97, where the U-phase pin 95 is coupled to the low-side drain 221, the V-phase pin 96 is coupled to the low-side drain 221a, and the W-phase pin 97 is coupled to the low-side drain 221b. In addition, in the present disclosure, the U-phase pin 95, V-phase pin 96, W-phase pin 97, and the ground pin 92 are all located on the same side of the package body 50.

The multi-phase SiC module packaging structure 1 of the present disclosure encapsulates at least two half-bridge modules 20, 20a, or three half-bridge modules 20, 20a, 20b within the same package body 50. This not only improves the conversion efficiency of the multi-phase SiC module and reduces the assembly cost of the half-bridge modules, but also achieves a dual-sided heat dissipation effect by exposing both the heat dissipation surface 11 of the heat dissipation substrate 10 and the second surface 62 of the heat dissipation plate 60 from the package body 50. As a result, the thermal performance of the multi-phase SiC module is improved, and power loss is reduced.

It should be noted that many of the above-mentioned embodiments are given as examples for description, and the scope of the present disclosure should be limited to the scope of the following claims and not limited by the above embodiments.

What is claimed is:

1. A multi-phase silicon carbide (SiC) packaging structure, comprising:
a heat dissipation substrate provided with a metal routing;
a lead frame coupled to the heat dissipation substrate, the lead frame including a power pin and a ground pin;
a plurality of half-bridge modules connected in parallel between the power pin and the ground pin, each of the half-bridge modules comprising a high-side SiC transistor, a low-side SiC transistor, and a first clip, wherein the high-side SiC transistor and the low-side SiC transistor are flip-chip mounted on corresponding locations of the metal routing of the heat dissipation substrate, and a source of the high-side SiC transistor is coupled to a drain of the low-side SiC transistor through the first clip and the metal routing; and
a package body, encapsulating the heat dissipation substrate, the half-bridge modules and a portion of the lead frame.

2. The packaging structure as claimed in claim 1, further comprising at least one second clip, wherein the power pin is coupled to the drain of each of the high-side SiC transistor through the at least one second clip and the metal routing.

3. The packaging structure as claimed in claim 1, further comprising at least one third clip, wherein the ground pin is coupled to the source of each of the low-side SiC transistor through the at least one third clip and the metal routing.

4. The packaging structure as claimed in claim 1, further comprising a heat dissipation plate, the heat dissipation plate having a first surface and a second surface opposite to the first surface, the package body comprising a package top surface, wherein the first surface is coupled to the drain of each of the low-side SiC transistors through the at least one first clip, and the second surface is exposed from the package top surface.

5. The packaging structure as claimed in claim 1, wherein the package body comprises a package bottom surface, the heat dissipation substrate is a Direct Bond Copper (DBC) substrate, a Direct Bond Aluminum (DBA) substrate, or an Active Metal Brazing (AMB) substrate, and the heat dissipation substrate includes a heat dissipation surface, the heat dissipation surface is exposed from the package bottom surface.

6. The packaging structure as claimed in claim 1, wherein the power pin and the ground pin are respectively located on opposite sides of the package body.

7. The packaging structure as claimed in claim 1, the lead frame including a plurality of high-side gate pins and a plurality of low-side gate pins, and the high-side gate pins and the low-side gate pins are located on the same side of the package body.

8. The packaging structure as claimed in claim 1, wherein a number of the half-bridge modules is three, a number of the second clip is three, and a number of the third clips is three, wherein the power pin is coupled to the drain of each of the high-side SiC transistors in the three half-bridge modules through the three second clips and the metal routing, the ground pin is coupled to the source of each of the low-side SiC transistors in the three half-bridge modules through the three third clips and the metal routing, and when the multi-phase SiC module is a three-phase bridge inverter, the lead frame further includes a U-phase pin, a V-phase pin, and a W-phase pin.

9. The packaging structure as claimed in claim 8, wherein the U-phase pin, the V-phase pin, the W-phase pin, and the ground pin are located on the same side of the package body.
